(19) United States
(12) Patent Application Publication
(10) Pub. No.: US 2008/0308140 A1
(43) Pub. Date: Dec. 18, 2008

(54) Thermo-Electric Cooling Device

(75) Inventor: Yoshinori Nakamura, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: THE FURUKAWA ELECTRIC CO., LTD., Chiyoda-ku, Tokyo (JP)

(21) Appl. No.: 11/573,789

(22) PCT Filed: Aug. 12, 2005
(86) PCT No.: PCT/JP2005/014848

§ 371 Date: Feb. 16, 2007

(30) Foreign Application Priority Data
Aug. 17, 2004 (JP) 2004-236923
Mar. 28, 2005 (JP) 2005-091834

(51) Int. Cl. H01L 35/00

(52) U.S. Cl. 136/200

(57) ABSTRACT

A thermo-electric cooling device includes at least one-layer resin substrate having electric connection regions existing with a predetermined pattern, thermo-electric semiconductor elements including a plurality of p-type thermo-electric semiconductor elements and n-type thermo-electric semiconductor elements arranged so as to correspond to the electric connection regions, and an electric circuit metal layer where the thermo-electric semiconductor elements are electrically connected in series via a junction layer in the electric connection regions. The electric connection regions are, for example, through holes, openings, or the like. The plurality of thermo-electric semiconductor elements are a plurality of pairs of p-type thermo-electric semiconductor elements and n-type thermo-electric conductive elements.

### TECHNICAL FIELD

The present invention relates to a large-sized and high performance thermoelectric cooler having thermoelectric semiconductor elements including plural pairs each of a p-type thermoelectric semiconductor element and an n-type thermoelectric semiconductor element.

### BACKGROUND ART

Thermoelectric semiconductor elements are generally formed by connecting p-type thermoelectric semiconductor elements and n-type thermoelectric semiconductor elements via metal electrodes in series to form pn junction pairs. The thermoelectric semiconductor elements have the Peltier effect such that when current flows into a pn junction pair one junction part is cooled and the other generates heat and the Seebeck effect such that electric power is generated when a temperature difference is given between both sides of a pn junction pair, and the thermoelectric semiconductor elements are used as a cooling apparatus or power generating apparatus.

Usually, thermoelectric semiconductor elements are used as integrally structured thermoelectric semiconductor elements by connecting several-tens-to-hundreds of pn junction pairs in series and sandwiching the pn junction pairs by two substrates having metal electrodes on the surface.

Here, p-type thermoelectric semiconductor elements (also referred to as “elements”) and n-type thermoelectric semiconductor elements are preferably arranged alternately along the longitudinal direction and horizontal direction. With this arrangement, the elements, which usually form a rectangular solid, are arranged with the highest density. Here, the density of arrangement of elements means a ratio of a sum of bottom areas of the elements to the area of a thermoelectric element substrate.

As the electrodes of connection portions appear alternately on a high-temperature side substrate and on low-temperature side substrate, such an arrangement of the elements as described above serves to minimize the length and maximize the width of wiring of the electrodes, which reduces the electric resistance of the electrodes to a minimum. Besides, as the electrode pattern is extremely simple, there are advantages such that soldering for connection between the elements and the electrodes is facilitated and it is unlikely that there occurs a short due to bridge over adjacent electrodes.

FIG. 10 is a view illustrating a conventional TEC (thermoelectric cooler) having ceramic substrates. As illustrated in FIG. 10, the conventional TEC has plural pairs of a p-type thermoelectric semiconductor element and an retype thermoelectric semiconductor element 102 each having element electrode metal layers, electric circuit metal layers 106 which form n type series electric circuits junction layers 103 bonding the electric circuit metal layers and the element electrode metal layers and ceramic substrates 110. In other words, in the conventional TEC, the thermoelectric semiconductor elements 102 are vertically sandwiched by the ceramic substrates 110 having circuits thereon.

FIG. 11 is a view illustrating a conventional TEC having separator. This type of TEC is called “skeleton”, and as illustrated in FIG. 11, it has no ceramic substrate on and under the thermoelectric semiconductor elements 102. The TEC of this structure has an insulating plate 105, called separator, at the intermediate art of the thermoelectric semiconductor elements 102 to hold the predetermined shape. In order to support a large number of thermoelectric semiconductor elements 102, the separator needs to have some given thickness.

FIG. 12 is a view illustrating a conventional TEC having only one ceramic substrate. The ceramic substrate of this TEC exists at only one side, and this TEC is called “half skeleton”.

In any of these cases, the performance of the TEC depends on the height of elements and the high performance is achieved by lowering the height of elements.

Patent document: Japanese patent application publication No. 7-22657

### DISCLOSURE OF THE INVENTION

### Problems to be Solved by the Invention

The TEC dissipates and absorbs heat by being energized. In a conventional TEC having ceramic substrates illustrated in FIG. 10, the ceramic substrates expand by a temperature difference of this TEC and shear stress concentrates on thermoelectric semiconductor elements, and therefore, reliability is difficult to be assured. For this reason, the size is typically limited to 30 to 40 nm square. When the height of the thermoelectric semiconductor elements is lowered for high performance, the size limits are further lowered which becomes a problem. Further, the percentage of ceramic substrate in the TEC material cost is large and two ceramic substrates are needed in one TEC.

In the conventional TEC having a separator illustrated in FIG. 11, high performance is expected by making the elements thinner. However, as described above, the separator needs to have some given thickness. The thickness of the separator is the height limits of elements, and this shows there is limitations of the high performance. As the TEC has no ceramic substrate, circuits are exposed. Further, as there is nothing existing between circuits, there is a possibility that thermal interface (silicon grease) may flow therein and if the thermal interface flows therein, the performance is lowered, which presents a problem.

Further, the electrodes are independently provided, it is necessary to open up the space between the electrodes so as to prevent a short. Hence, there is a problem that an area of each electrode for heat transmission is reduced and the thermal resistance is enlarged. In a conventional TEC having only one ceramic substrate as illustrated in FIG. 12, the thermal resistance of the ceramic substrate is large, and usage of the ceramic substrate increases the cost. Further, as it is required to open up the space between the electrodes so as to prevent a short, the area of each electrode for heat transmission becomes smaller and the thermal resistance becomes larger.

Hence, the present invention has an object to provide a thermoelectric cooler having a reduced stress on thermoelectric semiconductor elements, an enlarged heat transmission area by setting the space between the electrodes narrower, a reduced thermal resistance and high performance and being allowed to be manufactured at low cost and much larger.

### Means for Solving the Problems

In order to solve the above-mentioned problems, the inventors of the present invention have conducted studies intensively. As a result, they have found that when a pair of resin substrates having given electric connection regions (for example, through-holes, openings) is used instead of ceramic substrates, the through-holes are filled with metal having excellent thermal and electric conductivities to form filling metal layers and electric circuit metal layers are arranged so as to sandwich the resin substrates so that respective surfaces of the thermoelectric semiconductor elements are connected to the electric circuit metal layers via the filling metal layers, a thus obtained thermoelectric cooler has the thermoelectric semiconductor elements thinner, narrow-spaced electrodes and high performance and is less expensive and allowed to be much larger.

The present invention was carried out in view of the above described findings. A thermoelectric cooler according to a first aspect of the present invention is a thermoelectric cooler comprising:

at least one resin substrate having electric connection regions existing with a given pattern;

thermoelectric semiconductor elements including a plurality of p-type thermoelectric semiconductor elements and a plurality of n-type thermoelectric semiconductor elements arranged corresponding to the electric connection regions; and

electric circuit metal layers arranged on an opposite surface of the resin substrate to the thermoelectric semiconductor elements, and with which the thermoelectric semiconductor elements are electrically connected in series via junction layers in the electric connection regions.

A thermoelectric cooler according to a second aspect of the present invention is a thermoelectric cooler in which the electric connection regions are through-holes and the thermoelectric cooler further comprises filling metal layers filled in the through-holes for heat and electric conduction and existing between the junction layers and the electric circuit metal layers.

A thermoelectric cooler according to a third aspect of the present invention is a thermoelectric cooler in which the filling metal layers and the junction layers are made of different materials.

A thermoelectric cooler according to a fourth aspect of the present invention is a thermoelectric cooler in which the filling metal layers and the junction layers are of an identical material and formed integrally.

A thermoelectric cooler according to a fifth aspect of the present invention is a thermoelectric cooler in which the electric connection regions are openings.

A thermoelectric cooler according to a sixth aspect of the present invention is a thermoelectric cooler in which each of the openings has a cross section larger than a cross section of each of the thermoelectric semiconductor elements.

A thermoelectric cooler according to a seventh aspect of the present invention is a thermoelectric cooler in which each of the openings has a cross section equal in size to or smaller than a cross section of each of the thermoelectric semiconductor elements.

A thermoelectric cooler according to an eighth aspect of the present invention is a thermoelectric cooler further comprising an Ni plating layer on a thermoelectric semiconductor element side surface of each of the electric circuit metal layers.

A thermoelectric cooler according to a ninth aspect of the present invention is a thermoelectric cooler further comprising an Ni plating on a thermoelectric semiconductor element side surface of each of the filling metal layers.

A thermoelectric cooler according to a tenth aspect of the present invention is a thermoelectric cooler in which the at least one resin substrate comprises two resin substrates arranged to sandwich the thermoelectric semiconductor element, and a pair of the electric circuit metal layers are arranged to sandwich the two resin substrates.

A thermoelectric cooler according to an eleventh aspect of the present invention is a thermoelectric cooler further comprising a different substrate from the resin substrate, wherein the at least one resin substrate comprises one resin substrate, one-side surfaces of the thermoelectric semiconductor elements are connected to the corresponding electric circuit metal layers via the junction layers while the-other-side surfaces of the thermoelectric semiconductor elements are connected to electric circuit metal layers arranged on a thermoelectric semiconductor element side of the different substrate.

A thermoelectric cooler according to a twelfth aspect of the present invention is a thermoelectric cooler further comprising: a pair of filling metal layers formed so as to sandwich each of the thermoelectric semiconductor elements, the thermoelectric semiconductor elements being connected to the electric circuit metal layers via the corresponding filling metal layers.

A thermoelectric cooler according to a thirteenth aspect of the present invention is a thermoelectric cooler in which the junction layers are provided by printing, a dispenser or the like.

A thermoelectric cooler according to a fourteenth aspect of the present invention is a thermoelectric cooler in which the junction layers are provided in advance on surfaces of filing metal layers by plating.

A thermoelectric cooler according to a fifteenth aspect of the present invention is a thermoelectric cooler in which each of the resin substrates is a flexible resin of polyamide, glass epoxy or aramid.

A thermoelectric cooler according to a sixteenth aspect of the present invention is a thermoelectric cooler further comprising insulating layers formed on outer surfaces of the electric circuit metal layers.

A thermoelectric cooler according to a seventeenth aspect of the present invention is a thermoelectric cooler in which the different substrate is a heat distributing plate or a base plate for heat dissipating fins.

A thermoelectric cooler according to an eighteenth aspect of the present invention is a thermoelectric cooler in which peripheries of the substrates vertically aligned are bonded.

A thermoelectric cooler according to another aspect of the present invention is a thermoelectric cooler in which the upper surfaces of the abovementioned filling metal layers are jutting from the upper surface of the resin substrate toward the thermoelectric semiconductor elements.

A thermoelectric cooler according to another aspect of the present invention is a thermoelectric cooler in which the filling metal layers filled in the aforementioned through-holes are of a material less in thermal and electric resistances.

### EFFECT OF THE INVENTION

As a substrate of a thermoelectric cooler of the present invention utilizes a less-expensive insulating resin as compared with a conventional substrate using ceramic the thermoelectric cooler can be manufactured at a lower cost than that of a conventional TEC. A thermoelectric cooler of this invention has a structure using no ceramic substrate which is poor in thermal conductivity, the thermoelectric cooler has the thermal resistance reduced. Not using ceramic substrate, the thermoelectric cooler can achieve high reliability with less stress caused by distortion associated with upsizing of the TEC area. As the thermoelectric cooler is structured to reduce the stress because it uses no ceramic substrate, the thermoelectric cooler is allowed to be upsized. Through-holes serve to reduce stress on the elements.

As a thermoelectric cooler is structured to have no separator, it is permitted to have high performance with no lower height limits of thermoelectric semiconductor elements. As each circuit is formed on a substrate, the space between electrodes can be set narrower and the heat transmission area can be enlarged thereby allowing high performance. As circuits and elements are separated by a resin substrate, the possibility of the occurrence of a short in soldering is lowered and a higher manufacturing yield can be achieved. As insulating resin exists between circuits, there is an effect of preventing heat-conductive grease from flowing therein, and thereby, fluctuation in performance by assembly is reduced. Usage of a resin substrate provides flexible usage.

### BRIEF DESCRIPTION OF THE DRAWINGS

FIG. 1 is a cross sectional view schematically illustrating a thermoelectric cooler of the present invention;

FIG. 2 is a cross sectional view schematically illustrating a substrate structure utilized in the present invention;

FIG. 3 is a cross sectional view illustrating a thermoelectric cooler according to another embodiment of the present invention;

FIG. 4 is a view for illustrating a positional relationship between openings formed in a resin substrate and electric circuit metal layers;

FIG. 5 is a cross sectional view of FIG. 4;

FIG. 6 is a cross sectional view illustrating a thermoelectric cooler having no filling metal layer;

FIG. 7 is a view illustrating a thermoelectric cooler having resin substrates bonded at the peripheries;

FIG. 8 is a cross sectional view of FIG. 7;

FIGS. 9(a) and (b) are partially-enlarged views thereof;

FIG. 10 is a view illustrating a conventional TEC having ceramic substrates;

FIG. 11 is a view illustrating a conventional TEC having separator; and

FIG. 12 is a view illustrating a conventional TEC having only one ceramic substrate.

### EXPLANATION OF REFERENCE NUMERALS

1 thermoelectric cooling device of this invention
2, 12 thermoelectric semiconductor element
3-1, 3-2, 13-1, 13-2 resin substrate
4-1, 4-2 through-hole
5-1, 5-2, 15-1, 15-2 junction layer
6-1, 6-2, 16-1, 16-2 electric circuit metal layer
7-1, 7-2 filling metal layer
8-1, 8-2 insulating layer
10 thermal transfer plate
17-1, 17-2 opening
20-1, 20-2 outer circumference of resin substrate
21-1, 21-2 flame
102 thermoelectric semiconductor element
103 junction layer
105 separator
106 electric circuit metal layer
110 ceramic substrate

With reference to the drawings, a thermoelectric cooling device of this invention is described in detail below.

A thermoelectric cooling device according to a first embodiment of this invention is a thermoelectric cooling device having: at least one flexible resin substrate having electric connection regions existing with a give pattern; thermoelectric semiconductor elements including a plurality of p-type thermoelectric semiconductor elements and a plurality of n-type thermoelectric semiconductor elements arranged corresponding to the electric connection regions; electric circuit metal layers which are arranged on an opposite surface of the resin substrate to the thermoelectric semiconductor elements and with which the thermoelectric semiconductor elements are electrically connected in series via a junction layer in the electric connection regions. The electric connection regions are through-holes, openings or the like.

When a p-type thermoelectric semiconductor element and an n-type thermoelectric semiconductor element are taken as a pair, the above-mentioned thermoelectric semiconductor elements may include plural pairs.

The above-mentioned at least one resin substrate may have two resin substrates arranged to have the thermoelectric semiconductor elements sandwiched therebetween, and a pair of electric circuit metal layers may be arranged to sandwich the two resin substrates.

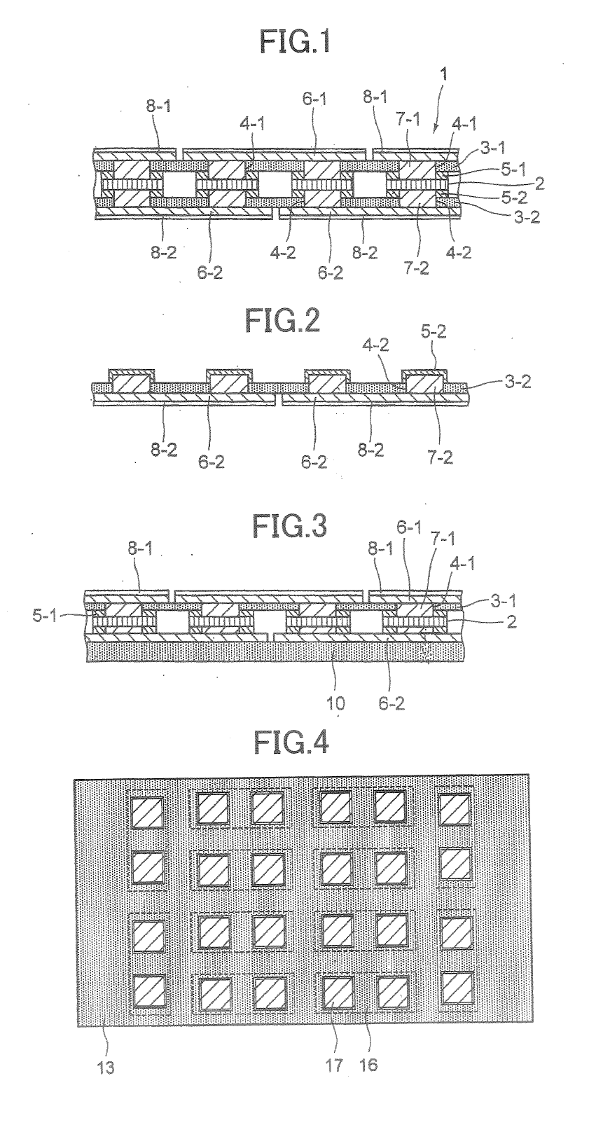

FIG. 1 is a cross sectional view schematically illustrating a thermoelectric cooler of the present invention. This embodiment utilizes two flexible resin substrates having through-holes as electric connection regions, and the two resin substrates are arranged so as to separate thermoelectric semiconductor elements and respective-side electric circuit metal layers. The thermoelectric semiconductor elements and electric circuit metal layers are connected via filling metal layers filled in the through-holes. In other words, as illustrated in FIG. 1 the resin substrates 3-1, 3-2 having through-holes 4-1, 4-2 with a given pattern are arranged to sandwich thermoelectric semiconductor elements 2, and the through-holes are filled with metal to form the filling metal layers 7-1, 7-2. The filling metal layers 7-1, 7-2 are formed for example by depositing Cu plating on the electric circuit metal layers 6-1, 6-2. Then, arranged on the thus-formed filling metal layers are the thermoelectric semiconductor elements 2 via junction layers 5-1, 5-2. Each of the electric circuit metal layers is arranged on a surface of the resin substrate opposite to the surface on which the thermoelectric semiconductor elements are positioned via the junction layer. In other words, the resin substrates are used with through-holes formed therein with the given pattern, which enables heat and electric conduction.

In this embodiment, the filling metal layers and the junction layers are made of different materials as described above, however, they may be made of the same material. For example, each filling metal layer may be of Cu plating while each junction layer may be of solder. Or, both of them may be made of solder.

Formed on the outer surfaces of the electric circuit metal layers are insulating layers 8-1, 8-2, respectively. Each electric circuit metal layer may be coated with an insulating film according to usage, or resin foil, for example. When each electric circuit metal layer is coated with the insulating film, the film is required to be thinner and excellent in heat conductivity, which properties enable reduction of thermal resistance.

As described above, the filling metal layers are arranged to sandwich the plural pairs of p-type and n-type thermoelectric semiconductor elements 2 vertically via the junction layers, and the resin substrates in which the through-holes are filled with the filling metal layers are fixedly arranged in pair to be opposed to each other. Besides, arranged on the outer surface of the resin substrates are the electric circuit metal layers. In this way, the plural pairs of p-type and n-type thermoelectric semiconductor elements 2 are connected in series by the electric circuit metal layers and via the filling metal layers.

As is clear from FIG. 1, in this invention, there is no separator used, as opposed to the conventional one. As the thermoelectric semiconductor elements are vertically fixed by the resin substrates, the filling metal layers filled in the through-holes of the resin substrates and the electric circuit metal layers arranged on the outer surfaces of the respective resin substrates, there is nothing to limit the thickness of each thermoelectric semiconductor element mechanically and each thermoelectric semiconductor element is allowed to be thinner, which enables high performance of the thermoelectric cooler.

FIG. 2 is a cross sectional view schematically illustrating a substrate structure utilized in the present invention. Basically, two substrates each having a substrate structure of FIG. 2 are used to sandwich the thermoelectric semiconductor elements. Further, the substrate structure illustrated in FIG. 2 may be used in combination with another substrate (for example, heat distributing plate, base plate for heat dissipating fins ceramic substrate as described later).

As described above, the electric circuit metal layer 6-2 is arranged over one surface of the resin substrate 3-2 having through-holes. The through-holes 4-2 of the resin substrate 3-2 on the electric circuit metal layer 6-2 are filled with metal which is excellent in thermal and electrical conductivities of Cu or the like thereby to form the filling metal layers 7-2. The through-holes 4-2 are arranged with a given pattern corresponding to arrangement of the thermoelectric semiconductor elements. The filling metal layers are formed by depositing Cu plating as described above. The upper surface of each filling metal layer is higher than that of the resin substrate.

Formed on the filling metal layers are junction layers 5-2 to cover the filling metal layers entirely. A part of each of the junction layers 5-2, which is positioned on the upper surface of the corresponding filling metal layer shown in FIG. 2, mostly moves horizontally as shown in FIG. 1 and then, the thermoelectric semiconductor element and the filling meal layer are connected via the junction layer. In this way, as the electric circuit metal layer and the thermoelectric semiconductor elements are arranged as separated by the resin substrate, the probability of a short during soldering is lowered, which enables enhancement of yields. Further, as illustrated in FIG. 2, the electric circuit is formed on the resin substrate, each space between electrodes can be set narrower and a larger heat transmission area can be achieved. Furthermore, as insulating resin exists between electric circuits, heat-conductive grease is effectively prevented from flowing therein, whereby performance fluctuation by assembly is reduced.

The substrates in pair each having a structure of FIG. 2 are used to sandwich thermoelectric semiconductor elements thereby to constitute a thermoelectric cooler of this invention. Then, as described above, the junction layers 5-1, 5-2 positioned on the upper surfaces of the filling metal layers 7-1, 7-2 mostly move horizontally to bring the thermoelectric semiconductor elements 2 into connection to the filling metal layers 7-1, 7-2 via the junction layers 5-1, 5-2.

FIG. 3 is a cross sectional view illustrating a thermoelectric cooler according to another embodiment of the present invention. The thermoelectric cooler in this embodiment uses one resin substrate at one side and another substrate at the other side. In other words, the resin substrate 3-1 having through-holes 4-1 with the aforementioned given pattern is used and the through-holes are filled with metal to form filling metal layers 7-1. The filling metal layers 7-1 are formed by depositing Cu plating on the electric circuit metal layers 6-1. Arranged on the thus formed filling metal layers are the thermoelectric semiconductor elements 2 via the junction layers 5-1.

On the opposite side to the resin substrate, a heat distributing plate, for example, having insulating layers on the surface is provided. Formed on the insulating layers of the heat distributing plate are electric circuit metal layers 6-2. The thermoelectric semiconductor elements 2 are connected to the electric circuit metal layers via the junction layers. Here, the thermal transfer plate may be replaced by a heat dissipating fin base plate having insulating layers formed on its surface.

Formed on the outer surface of each electric circuit metal layer 6-1 is an insulating layer 8-1. Specifically, connected onto the plural pairs of p-type and n-type thermoelectric semiconductor elements 2 on the upside are filling metal layers via junction layers, accordingly a resin substrate having through-holes filled with metal layers is fixedly arranged and the electric circuit metal layer is arranged on the outer surface of the resin substrate. Further connected onto the plural pairs of p-type and n-type thermoelectric semiconductor elements 2 on the downside are junction layers, an element electrode metal layer formed on the electric circuit metal layer, and the electric circuit metal layer is arranged on the thermal transfer plate having an insulating layer on its surface. Thus, the p-type thermoelectric semiconductor elements and n-type thermoelectric semiconductor elements in plural pairs are electrically connected in series by the electric circuit metal layer via the filling metal layers.

Also in the thermoelectric cooler using a resin substrate on its one surface as illustrated in FIG. 3, the same effect as described above can be obtained in the upper half. That is, a part of each of the junction layers, which is positioned on the upper surface of the corresponding filling metal layer, mostly moves horizontally and then, the thermoelectric semiconductor element and the filling metal layer are connected via the junction layer. In this way, as the electric circuit metal layer and the thermoelectric semiconductor elements are arranged as separated by the resin substrate, the probability of a short during soldering is reduced, which enables enhancement of yields. Further, the electric circuit is formed on the resin substrate, each space between electrodes can be set narrower and a larger heat transmission area can be achieved. Furthermore, as insulating resin exists between electric circuits, heat-conductive grease is effectively prevented from flowing therein, whereby performance fluctuation by assembly is reduced.

Here, an Ni plating layer may be provided to the above-described element side of each filing metal layer. This provision of an Ni plating layer prevents change/deterioration over time of the surface of the filling metal layer and allows wettability in soldering to be improved.

Further, the above-described junction layers may be provided by printing, dispenser or the like, or provided in advance on the respective surfaces of the filling metal layers by plating or the like. As the junction layers are provided in advance, savings in time and manpower during assembly can be realized.

A thermoelectric cooler according to another embodiment of the present invention is a thermoelectric cooler having: at least one flexible resin substrate having openings each larger than the cross section of a thermoelectric semiconductor element and formed with a give pattern; a plurality of pairs of p-type and n-type thermoelectric semiconductor elements arranged corresponding to the openings; electric circuit metal layers which are arranged on an outer surface of the resin substrate and with which the thermoelectric semiconductor elements are electrically connected in series via junction layers. In other words, in this embodiment, there is no filling metal layer and the p-type thermoelectric semiconductor elements and n-type thermoelectric semiconductor elements are connected to the electric circuit metal layer via the junction layers.

Here, as described above, the cross section of each opening may be larger than that of a thermoelectric semiconductor element and the cross section of the opening may be equal in size to or smaller than that of a thermoelectric semiconductor element. When the cross section of each opening is equal to or smaller than that of the thermoelectric semiconductor element, the opening is filled with solder to serve like the through-hole as described above.

FIG. 4 is a view for illustrating a positional relationship between openings formed in a resin substrate and electric circuit metal layers. FIG. 5 is a cross sectional view of the structure shown in FIG. 4.

As illustrated in FIGS. 4 and 5, the flexible resin substrate 13 of polyimide, for example, are provided with a plurality of openings 17 formed with a given pattern. The openings 17 correspond in position to the plural pairs of p-type and n-type thermoelectric semiconductor elements to be arranged. The electric circuit metal layers 16 are arranged on an outer surface of the resin substrate 13 and as described later, the plural pairs of p-type and n-type thermoelectric semiconductor elements are electrically connected in series via the junction layers.

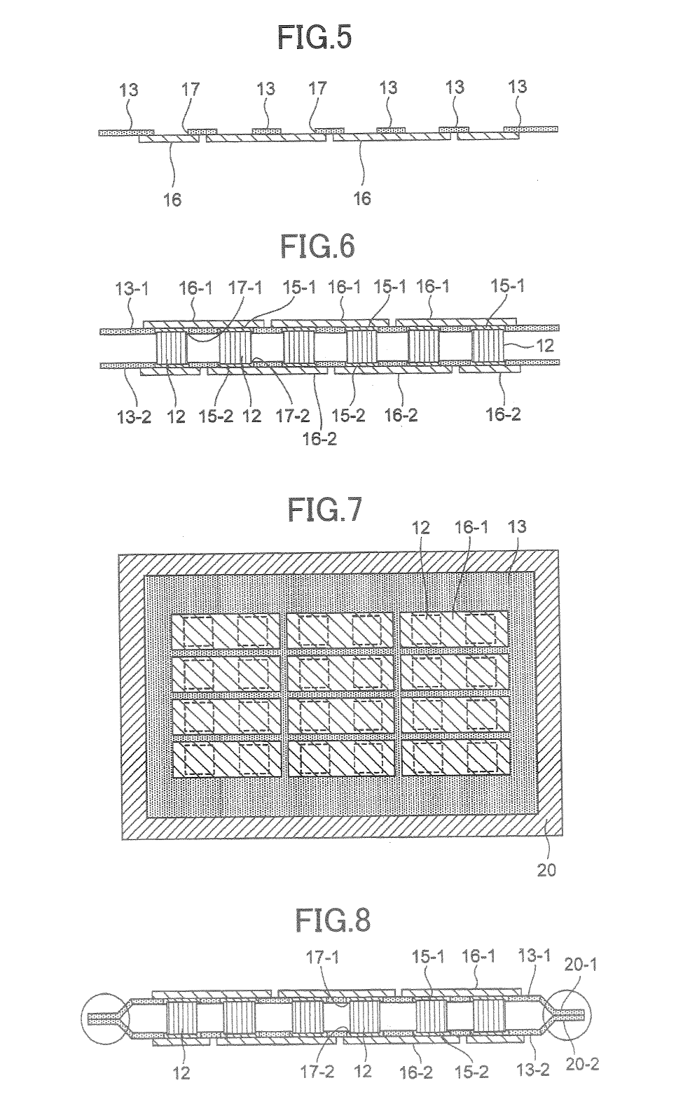

FIG. 6 is a cross sectional view schematically illustrating a thermoelectric cooler having no filling metal layer. As illustrated n FIG. 6, resin substrates 13-1, 13-2 having openings 17-1, 17-2 with a given pattern are arranged to sandwich thermoelectric semiconductor elements 12. The thermoelectric semiconductor elements 12 are arranged between the openings 17-1 and 17-2 and connected to the electric circuit metal layers 16-1, 16-2 via the junction layers 15-1, 15-2, respectively. Here, the electric circuit metal layers 16-1, 16-2 are arranged on opposite surfaces of the resin substrates 13-1, 13-2, respectively, to the surfaces on which the thermoelectric semiconductor elements 12 are arranged. As described above, in this embodiment, no filling metal layer is formed in each opening and the thermoelectric semiconductor elements are connected to the electric circuit metal layers via the junction layers 15-1, 15-2. Thus, the plural pairs of p-type and n-type thermoelectric semiconductor elements are electrically connected in series by the electric circuit metal layers via the junction layers.

Further, each of the above-described electric circuit metal layers may be provided with an Ni plating layer on thermoelectric semiconductor element side. This provision of an Ni plating layer prevents change/deterioration over time of the surface of the electric circuit metal layers and allows wettability in soldering to be improved.

Further, the above-described junction layers may be provided by printing, dispenser or the like, or provided in advance on the respective surfaces of the filling metal layers by plating or the like. As the junction layers are provided in advance, savings in time and manpower during assembly can be realized.

In the thermoelectric cooler of this embodiment, as there is no need to deposit plating, for example, in a through-hole as a filling metal layer, the manufacturing cost can be reduced and the manufacturing steps can be lessened.

Further, in a thermoelectric cooler of another embodiment of the present invention, the above-described resin substrates vertically aligned are bonded at their peripheries by an adhesive agent or solder.

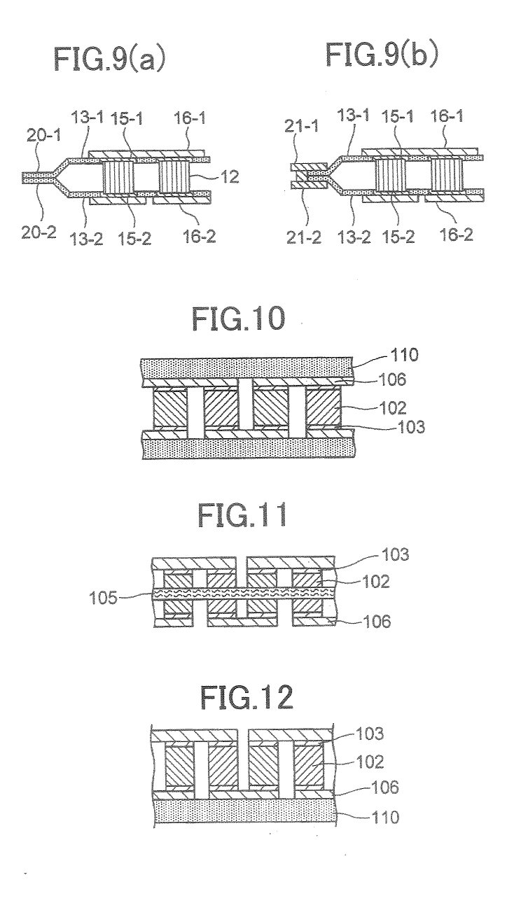

FIG. 7 is a view illustrating thermoelectric cooler having resin substrates bonded at their peripheries. FIG. 8 is a cross sectional view of the thermoelectric cooler of FIG. 7. FIGS. 9(a) and 9(b) are partially-enlarged views.

As illustrated in FIGS. 7 and 8, resin substrates 13-1, 13-2 having openings 17-1, 17-2 with a given pattern are arranged to sandwich thermoelectric semiconductor elements 12. The thermoelectric semiconductor elements 12 are arranged in the openings 17-1, 17-2 and connected to electric circuit metal layers 16-1, 16-2 via unction layers 15-1, 15-2, respectively. Here, the electric circuit metal layers 16-1, 16-2 are arranged on opposite surfaces of the respective resin substrates 13-1, 13-2 to the thermoelectric semiconductor elements 12. The plural pairs of p-type and n-type thermoelectric semiconductor elements are electrically connected in series by the electric circuit metal layers via the junction layers. Further, the peripheries of the resin substrates 13-1, 13-2 are bonded by an adhesive agent or solder, which are illustrated by circles in FIG. 8.

As illustrated in FIG. 9(a), the peripheries 20-1, 20-2 of the vertically aligned resin substrates 13-1, 13-2 are bonded by the adhesive agent. Further, as illustrated in FIG. 9(b), the peripheries 20-1, 20-2 of the vertically aligned resin substrates 13-1, 13-2 are bonded by soldering with use of frames 21-1, 21-2 of the same material as that of the electric circuit metal layers.

In this way, as the peripheries of the two flexible resin substrates are bonded, the thermoelectric cooler has an outside-air blocking structure, and thereby a dew-condensation prevention structure of the thermoelectric semiconductor elements can be easily formed.

The p-type and n-type thermoelectric semiconductor elements only need to have a thermoelectric property and not limited to Bi—Te semiconductor alloy. Any alloy having a thermoelectric property can be used.

Each electric circuit metal layer (that is, metal electrodes) is of any one selected from Cu, Cr, Ni, Ti, Al, Au, Ag and Si, alloy of any of them or formed by depositing plural layers of them. Each electric circuit metal layer needs to be excellent in electrical conductivity and thermal conductivity. The electric circuit metal layer may be formed by, for example, wet-coating, sputtering, vacuum deposition, ion-plating or the like.

Each resin substrate is preferably of polyimide, glass epoxy or aramid resin having flexibility. When any of these materials is used as a flexible substrate to support an electric circuit or elements, the thickness of the resin substrate is preferably 10 μm to 200 μm. However, these materials and values of thickness are not for limiting substrates used in the present invention. The resin substrates only reed to be capable of reducing stress on thermoelectric semiconductor elements, junction layers, plating layers electric circuit metal layers and the like when the substrate is heated or cooled within the range of manufacturing conditions or usage conditions or when an upper substrate and a lower substrate are different in temperature.

Each filling metal layer is preferably of an electrically and thermally conducting material having low electrical and thermal resistances, such as Cu.

Each element electrode metal layer is of any one element selected from Cu, Ti, Cr, W, Mo, Pt, Zr, Ni, Si, Pd and C, alloy of any of them, or may be formed by depositing plural layers of them. The element electrode metal layer is formed on each surface of a p-type or n-type thermoelectric semi-conductor element.

Each element electrode metal layer is manufactured by wet coating, sputtering, vacuum deposition, ion plating or the like, solely or in combination of them.

Each junction layer serves to bond thermoelectric semiconductor elements having element electrode metal layers to an electric circuit metal layer.

Each junction layer only needs to be of a brazing material enabling bonding at temperatures of 300° C. or less, and is preferably of any one of Au, Ag, Ge, In, P, Si, Sn, Sb, Pb, Bi, Zn and Cu or an alloy containing any of them.

In addition, a material used in soldering utilizes various soldering metals including Sn—Sb, Sn—Cu, Sn—Ag, Sn—Ag—Si—Cu, Sn—Zn, Sn—Pb, Au—Sn metals.

Each junction layer may be formed by paste printing, wet coating, sputtering, vacuum deposition or the like.

The present invention provides a thermoelectric cooler capable of reducing stress on elements, having a heat transmission area enlarged by setting a space between electrodes narrower, being less expensive, low in thermal resistance and excellent in performance and permitting upsizing, thereby with high industrial applicability.

1. A thermoelectric cooler comprising:
at least one resin substrate having electric connection regions existing with a given pattern;
thermoelectric semiconductor elements including a plurality of p-type thermoelectric semiconductor elements and a plurality of n-type thermoelectric semiconductor elements arranged corresponding to the electric connection regions; and
electric circuit metal layers arranged on an opposite surface of the resin substrate to the thermoelectric semiconductor elements, and with which the thermoelectric semiconductor elements are electrically connected in series via junction layers in the electric connection regions.

2. The thermoelectric cooler of claim 1, wherein the electric connection regions are through-holes, the thermoelectric cooler further comprising filling metal layers filled in the through-holes for heat and electric conduction and existing between the junction layers and the electric circuit metal layers.

3. The thermoelectric cooler of claim 2, wherein the filling metal layers and the junction layers are made of different materials.

4. The thermoelectric cooler of claim 2, wherein the filling metal layers and the junction layers are of an identical material and formed integrally.

5. The thermoelectric cooler of claim 1, wherein the electric connection regions are openings.

6. The thermoelectric cooler of claim 5, wherein each of the openings has a cross section larger than a cross section of each of the thermoelectric semiconductor elements.

7. The thermoelectric cooler of claim 5, wherein each of the openings has a cross section equal in size to or smaller than a cross section of each of the thermoelectric semiconductor elements.

8. The thermoelectric cooler of any one of claims 2 to 7, further comprising an Ni plating layer on a thermoelectric semiconductor element side surface of each of the electric circuit metal layers.

9. The thermoelectric cooler of claim 2 or 3, further comprising an Ni plating layer on a thermoelectric semiconductor element side surface of each of the filling metal layers.

10. The thermoelectric cooler of any one of claims 1 to 9, wherein the at least one resin substrate comprises two resin substrates arranged to sandwich the thermoelectric semiconductor element, and a pair of the electric circuit metal layers are arranged to sandwich the two resin substrates.

11. The thermoelectric cooler of any one of claims 1 to 9, further comprising a different substrate from the resin substrate, wherein the at least one resin substrate comprises one resin substrate, one-side surfaces of the thermoelectric semiconductor elements are connected to the corresponding electric circuit metal layers via the junction layers while the-other-side surfaces of the thermoelectric semiconductor elements are connected to electric circuit metal layers arranged on a thermoelectric semiconductor element side of the different substrate.

12. The thermoelectric cooler of any one of claims 2 to 4 and 8 to 10, further comprising: a pair of filling metal layers formed so as to sandwich each of the thermoelectric semiconductor elements, the thermoelectric semiconductor elements being connected to the electric circuit metal layers via the corresponding filling metal layers.

13. The thermoelectric cooler of any one of claims 1 to 7, wherein the junction layers are provided by printing, a dispenser or the like.

14. The thermoelectric cooler of any one of claims 2 to 4, wherein the junction layers are provided in advance on surfaces of filling metal layers by plating.

15. The thermoelectric cooler of any one of claims 1 to 14, wherein each of the resin substrates is a flexible resin of polyimide, glass epoxy or aramid.

16. The thermoelectric cooler of any one of claims 1 to 15, further comprising insulating layers formed on outer surfaces of the electric circuit metal layers.

17. The thermoelectric cooler of claim 11, wherein the different substrate is a thermal transfer plate or a base plate for heat dissipating fins.

18. The thermoelectric cooler of any one of claims 1 to 17, wherein peripheries of the substrates vertically aligned are bonded.
